(19) United States
(12) Patent Application Publication
(10) Pub. No.: US 2026/0068489 A1
(43) Pub. Date: Mar. 5, 2026

(54) DISPLAY DEVICE AND METHOD OF MANUFACTURING THE SAME

(71) Applicant: Samsung Display Co., LTD., Yongin-si (KR)

(72) Inventors: Tae Hyung HWANG, Yongin-si (KR); Seon Uk LEE, Yongin-si (KR); Chang Soon JANG, Yongin-si (KR)

(73) Assignee: Samsung Display Co., LTD., Yongin-si (KR)

(21) Appl. No.: 19/089,688

(22) Filed: Mar. 25, 2025

(30) Foreign Application Priority Data
Aug. 28, 2024 (KR) 10-2024-0115833

(51) Int. Cl. H10K 59/80; H10K 59/12; H10K 59/38

(52) U.S. Cl. CPC H10K 59/873; H10K 59/1201; H10K 59/38; H10K 59/879

(57) ABSTRACT

A display device includes a first substrate comprising a first support substrate including emission areas and light emitting elements disposed on the emission areas, a second substrate facing the first substrate, and a sealing layer bonding the first substrate and the second substrate together. The second substrate includes a second support substrate facing the first substrate, a color filter layer disposed on a surface of the second support substrate, a low refractive layer disposed on a portion of the color filter layer in the emission areas, and a first capping layer disposed on the color filter layer, including an inorganic insulating material, and covering the low refractive layer. The low refractive layer has a refractive index lower than the first capping layer.

### CROSS-REFERENCE TO RELATED APPLICATION(S)

This application claims priority to and benefits of Korean Patent Application No. 10-2024-0115833 under 35 U.S.C. § 119, filed on Aug. 28, 2024, in the Korean Intellectual Property Office (KIPO), the entire contents of which are incorporated herein by reference.

### BACKGROUND

### 1. Technical Field

The disclosure relates to a display device and a method of manufacturing the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions.

The display devices may be flat panel display devices such as liquid crystal display devices, field emission display devices, and light emitting display devices. Here, the light emitting display devices may include an organic light emitting display device including an organic light emitting element, an inorganic light emitting display device including an inorganic light emitting element such as an inorganic semiconductor, or a micro- or nano-light emitting display device including a micro-or nano-light emitting element.

An organic light emitting display device displays an image using light emitting elements, each including a light emitting layer of an organic light emitting material. The organic light emitting display device that displays an image using the self-light emitting elements may have relatively superior performance in terms of power consumption, response speed, luminous efficiency, luminance, and wide viewing angle, compared with other display devices.

In a display device, a surface from which light is emitted may include a display area where an image is displayed and a non-display area disposed adjacent to the display area. In the display area, emission areas that emit light with respective luminances and colors may be arranged.

### SUMMARY

The display device may include a first substrate that emits light from the emission areas with respective luminances and a second substrate that converts the light from the emission areas into respective colors.

The light emitted from the first substrate may be viewed outside the device through the second substrate. Accordingly, the second substrate may include a low refractive layer for improving light emission efficiency.

The low refractive layer may include an organic material instead of an inorganic material in order to have a relatively low refractive index. Therefore, there is a problem that a penetration path of oxygen or moisture formed due to the organic material of the low refractive layer.

Aspects of the disclosure provide a display device and a method of manufacturing the same, in which a penetration path of oxygen or moisture through a low refractive layer may be reduced or delayed.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a display device may include a first substrate including a first support substrate including emission areas and light emitting elements disposed on the emission areas, a second substrate facing the first substrate, and a sealing layer bonding the first substrate and the second substrate together. The second substrate may include a second support substrate facing the first substrate, a color filter layer disposed on a surface of the second support substrate, a low refractive layer disposed on a portion of the color filter layer in the emission areas, and a first capping layer disposed on the color filter layer, including an inorganic insulating material, and covering the low refractive layer. The low refractive layer may have a refractive index lower than the first capping layer.

The low refractive layer may include a transparent organic material and hollow silica particles dispersed in the transparent organic material, and the refractive index of the low refractive layer may be in a range of about 1.0 to about 1.5.

Each of the first support substrate and the second support substrate may include a display area in which the emission areas are arranged and a non-display area disposed around the display area, the display area may include a non-emission area between the emission areas, the color filter layer may include a light blocking portion disposed in the non-emission area and the non-display area and blocking light, and the low refractive layer may be disposed in a portion of the non-display area which is adjacent to the display area and in the display area.

The sealing layer may be disposed in the non-display area, and the low refractive layer may be spaced apart from the sealing layer.

The second substrate may further include a dam portion disposed on the color filter layer in the non-display area and surrounding the display area in a plan view, and the low refractive layer may be disposed in an area surrounded by the dam portion in a plan view.

The emission areas may include a first emission area emitting light of a first wavelength band, a second emission area emitting light of a second wavelength band lower than the first wavelength band and a third emission area emitting light of a third wavelength band lower than the second wavelength band, the color filter layer may further include a first filter portion disposed in the first emission area and transmitting the light of the first wavelength band, a second filter portion disposed in the second emission area and transmitting the light of the second wavelength band and a third filter portion disposed in the third emission area and transmitting the light of the third wavelength band, and the light blocking portion may be further disposed in the non-display area on the second support substrate.

The light emitting elements may emit light of a fourth wavelength band equal to or lower than the third wavelength band, and the second substrate may further include a color conversion layer disposed on the first capping layer and a second capping layer disposed on the first capping layer, including an inorganic insulating material and covering the color conversion layer. The color conversion layer may include a first color conversion portion disposed in the first emission area and converting the light of the fourth wavelength band into the light of the first wavelength band, a second color conversion portion disposed in the second emission area and converting the light of the fourth wavelength band into the light of the second wavelength band, a light transmitting portion disposed in at least a portion of the third emission area and transmitting the light of the fourth wavelength band, and a partition wall disposed between the first color conversion portion, the second color conversion portion, and the light transmitting portion.

The first substrate may include a circuit layer disposed on the first support substrate and comprising light-emitting pixel drivers electrically connected to the light emitting elements, respectively, an element layer disposed on the circuit layer and comprising the light emitting elements, and an enclosing layer covering the element layer. The element layer may further include anodes disposed in the emission areas, a pixel defining layer disposed in the non-emission area and covering edges of the anodes, a light emitting layer disposed on the anodes and the pixel defining layer and a cathode disposed on the light emitting layer, and each of the light emitting elements may have a structure in which the light emitting layer is disposed between an anode and the cathode facing each other.

According to an embodiment of the disclosure, a method of manufacturing a display device may include preparing a first substrate which comprises light emitting elements disposed in emission areas, preparing a second substrate, placing a sealing layer on the first substrate or the second substrate, and bonding the first substrate and the second substrate together using the sealing layer. The preparing of the second substrate may include placing a color filter layer on a second support substrate, placing a low refractive layer on a portion of the color filter layer in the emission areas, and placing a first capping layer which covers the low refractive layer by stacking an inorganic insulating material on the color filter layer.

In the placing of the low refractive layer, the low refractive layer may have a refractive index lower than the first capping layer.

Each of the first substrate and the second substrate may include a display area in which the emission areas are arranged and a non-display area disposed around the display area, the display area may include a non-emission area between the emission areas, the color filter layer, in the placing of the color filter layer, may include a light blocking portion disposed in the non-emission area and the non-display area and blocking light, and the low refractive layer, in the placing of the low refractive layer, may be placed in a portion of the non-display area which is adjacent to the display area and in the display area.

In the placing of the sealing layer, the sealing layer may be placed in the non-display area.

In the placing of the low refractive layer, the low refractive layer may include a transparent organic material and hollow silica particles dispersed in the transparent organic material, and the refractive index of the low refractive layer may be in a range of about 1.0 to about 1.5.

The placing of the low refractive layer may include placing a target material layer on a portion of the color filter layer by dropping a target material through a nozzle, and curing the target material layer.

The preparing of the second substrate may further include, before the placing of the low refractive layer, placing a dam portion spaced apart from the display area and surrounding the display area on the color filter layer in the non-display area, and the placing of the target material layer may include spreading the target material dropped onto the color filter layer in an area surrounded by the dam portion.

The placing of the low refractive layer may include placing a target material layer on a portion of the color filter layer by dropping a target material through a nozzle, preparing a temporary material layer by curing the target material layer on the color filter layer, placing a mask material layer on the temporary material layer, preparing an etch mask by removing the mask material layer except for a portion overlapping at least the display area in a plan view, and partially removing the temporary material layer using the etch mask.

The placing of the low refractive layer may include placing a sacrificial layer by removing a portion of the sacrificial layer, which overlaps at least the display area in a plan view, on the color filter layer, placing a target material layer covering the sacrificial layer, on the color filter layer, preparing a temporary material layer by curing the target material layer, and removing a portion of the temporary material layer, which is disposed on the sacrificial layer, together with the sacrificial layer.

According to an embodiment of the disclosure, a method of manufacturing a display device may include preparing a first substrate which comprises light emitting elements disposed in emission areas of a display area, preparing a second substrate, placing a sealing layer on the first substrate or the second substrate, and bonding the first substrate and the second substrate together using the sealing layer. The preparing of the second substrate may include placing a color filter layer on a second support substrate, placing a sacrificial layer by removing a portion of a sacrificial material layer, which overlaps at least the display area in a plan view, on the color filter layer, placing a target material layer covering the sacrificial layer, on the color filter layer, preparing a temporary material layer by curing the target material layer, and placing a low refractive layer in the emission areas on a portion of the color filter layer by removing a portion of the temporary material layer, which is disposed on the sacrificial layer, together with the sacrificial layer.

The preparing of the second substrate may further include placing a first capping layer covering the low refractive layer by stacking an inorganic insulating material on the color filter layer, and in the placing of the low refractive layer, the low refractive layer may have a lower refractive index than the first capping layer.

In the placing of the low refractive layer, the low refractive layer may include a transparent organic material and hollow silica particles dispersed in the transparent organic material, and the refractive index of the low refractive layer may be in a range of about 1.0 to about 1.5.

The second support substrate may include the display area in which the emission areas are arranged and a non-display area disposed around the display area, the display area may include a non-emission area between the emission areas, the color filter layer, in the placing of the color filter layer, may include a light blocking portion disposed in the non-emission area and the non-display area and blocking light, the low refractive layer, in the placing of the low refractive layer, may be placed in a portion of the non-display area which is adjacent to the display area and in the display area, and the sealing layer, in the placing of the sealing layer, may be placed in the non-display area.

According to an embodiment of the disclosure, an electronic device may include the display device and a processor that transmits an image data signal to the display device.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view of a display device according to embodiments;

FIG. 2 is a schematic cross-sectional view taken along line A-A′ of FIG. 1 according to an embodiment;

FIG. 3 is an enlarged view of part C of FIG. 2;

FIG. 4 is a plan view of a display area and a circuit layer of part B illustrated in FIG. 1;

FIG. 5 is a schematic block diagram of the circuit layer of part B illustrated in FIG. 1;

FIG. 6 is a schematic diagram of an equivalent circuit of a light-emitting pixel driver of FIG. 5;

FIG. 7 is a schematic cross-sectional view taken along line D-D′ of FIG. 4 according to embodiments;

FIGS. 8 and 9 are schematic cross-sectional views taken along line A-A′ of FIG. 1 according to embodiments;

FIG. 10 is a flowchart illustrating a method of manufacturing a display device according to embodiments;

FIG. 11 is a flowchart illustrating an operation of preparing a second substrate in FIG. 10 according to embodiments;

FIGS. 12, 13, 14, 15, 16, 17, 18, and 19 are schematic diagrams illustrating some operations of FIGS. 10 and 11;

FIG. 20 is a flowchart illustrating an operation of placing a low refractive layer in FIG. 11 according to an embodiment;

FIGS. 21, 22 and 23 are schematic diagrams illustrating operations of FIG. 20;

FIG. 24 is a flowchart illustrating an operation of preparing a second substrate according to an embodiment;

FIGS. 25, 26, and 27 are schematic diagrams illustrating operations of FIGS. 20 and 24;

FIG. 28 is a flowchart illustrating the operation of placing the low refractive layer in FIG. 11 according to an embodiment;

FIGS. 29, 30, 31, 32, and 33 are schematic diagrams illustrating operations of FIG. 28;

FIG. 34 is a flowchart illustrating the operation of placing the low refractive layer in FIG. 11 according to an embodiment; and

FIGS. 35, 36, 37, 38, and 39 are schematic diagrams illustrating operations of FIG. 34.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Further, the phrase “in a plan view” means when an object portion is viewed from above, and the phrase “in a schematic cross-sectional view” means when a cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

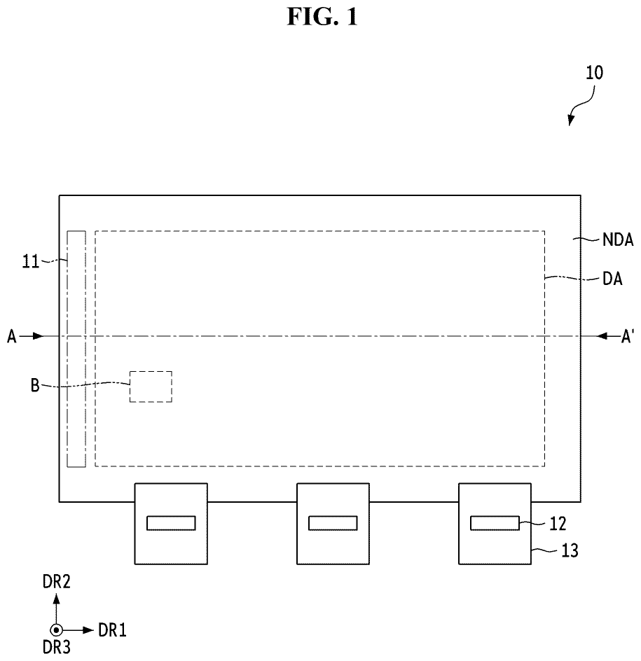

FIG. 1 is a plan view of a display device 10 according to embodiments.

Referring to FIG. 1, the display device 10 according to embodiments may be a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (IoT) devices.

The display device 10 may be a light emitting display device such as an organic light emitting display device using an organic light emitting diode, a quantum dot light emitting display device including a quantum dot light emitting layer, an inorganic light emitting display device including an inorganic semiconductor, or a micro- or nano-light emitting display device using a micro-or nano-light emitting diode. An embodiment that the display device 10 is an organic light emitting display device will be described below. However, the disclosure is not limited thereto and may be also applicable to display devices including an organic insulating material, an organic light emitting material, and a metal material.

The display device 10 may be formed flat, but the disclosure is not limited thereto. For example, the display device 10 may include a curved portion formed at left and right ends and having a constant or varying curvature. For example, the display device 10 may be formed to be flexible so that it can be curved, bent, folded, or rolled.

According to an embodiment, the display device 10 may be an organic light emitting display device.

As illustrated in FIG. 1, the display device 10 according to embodiments may include a quadrangular surface. However, this is merely an example, and the shape of the display device 10 is not limited to that illustrated in FIG. 1. In another embodiment, the display device 10 may include a polygonal or circular surface other than a quadrangular surface. In another embodiment, at least a portion of the display device 10 may be transformed from an unfolded shape to a curved, bent, folded, or rolled shape.

The surface of the display device 10 may include a display area DA from which light for displaying an image is emitted and a non-display area NDA surrounding the display area DA.

The display area DA may form most of the surface of the display device 10.

The non-display area NDA may be a frame-shaped area from which light for displaying an image is not emitted and which surrounds the display area DA. For example, the non-display area NDA may be maintained in a specific color such as black.

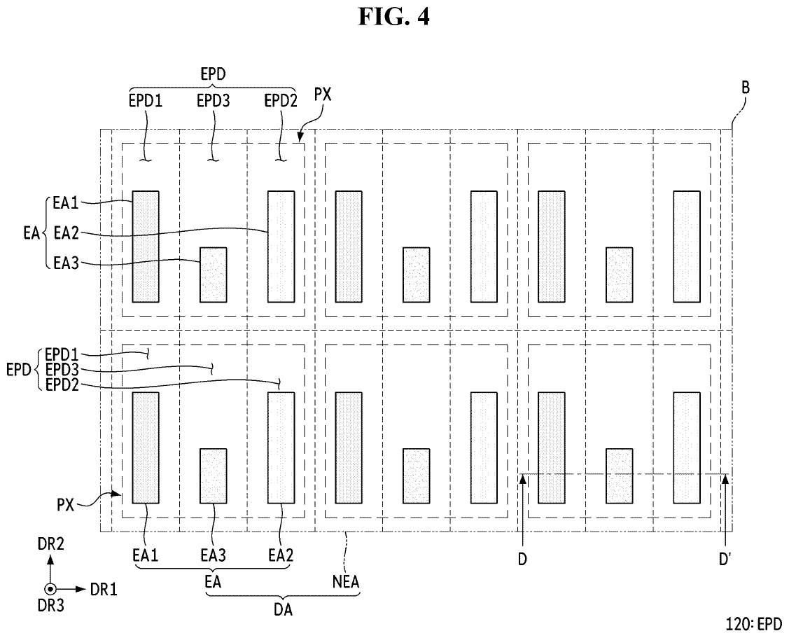

The display device 10 may include drivers 11 and 12 which transmit signals, voltages, or power to light-emitting pixel drivers EPD (see FIGS. 4, 5 and 6) disposed in the display area DA.

Among the drivers 11 and 12, a driver 11 which can be implemented as a relatively simple circuit may be disposed in the non-display area NDA.

Another drivers 12 among the drivers 11 and 12 may be prepared as integrated circuit chips and mounted on circuit boards 13 electrically connected to pads of the non-display area NDA. In another embodiment, the another drivers 12 may be mounted on the pads of the non-display area NDA.

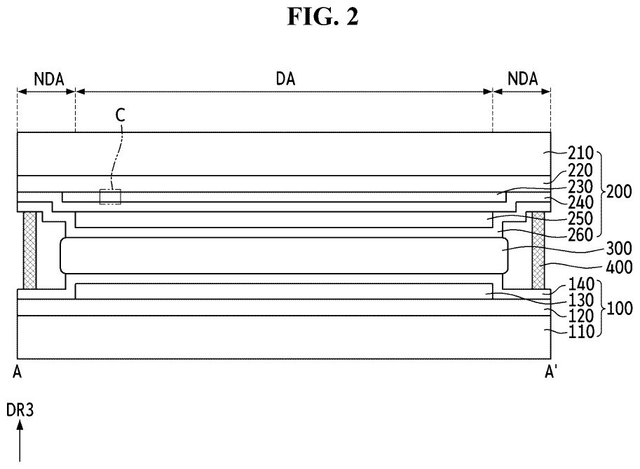

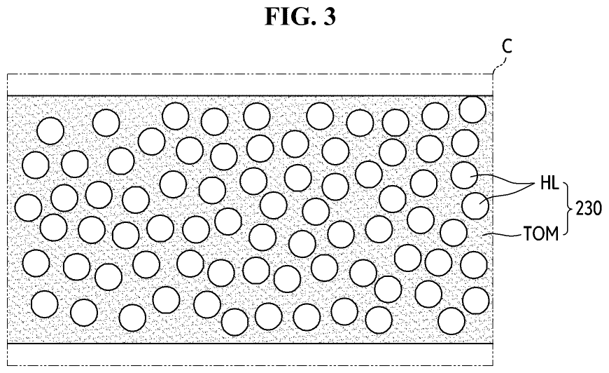

FIG. 2 is a schematic cross-sectional view taken along line A-A′ of FIG. 1. FIG. 3 is an enlarged view of part C of FIG. 2.

Referring to FIG. 2, the display device 10 according to embodiments may include a first substrate 100, a second substrate 200 facing the first substrate 100, and a sealing layer 400 bonding the first substrate 100 and the second substrate 200 together.

Each of the first substrate 100 and the second substrate 200 may include a display area DA from which light for displaying an image is emitted and a non-display area NDA which is disposed around the display area DA and from which light is not emitted.

The sealing layer 400 may be disposed in the non-display area NDA between the first substrate 100 and the second substrate 200.

The display device 10 may further include a filling layer 300 disposed between the first substrate 100 and the second substrate 200. The filling layer 300 may be disposed at least in the display area DA and may fill a space between the first substrate 100 and the second substrate 200.

The first substrate 100 may include a first support substrate 110, a circuit layer 120 disposed on the first support substrate 110, an element layer 130 disposed on the circuit layer 120, and an enclosing layer 140 disposed on the element layer 130.

The second substrate 200 may include a second support substrate 210 facing the first substrate 100, a color filter layer 220 disposed on the second support substrate 210, a low refractive layer 230 disposed on a portion of the color filter layer 220 and overlapping emission areas EA (see FIG. 4) of the display area DA in the third direction DR3, and a first capping layer 240 disposed on the color filter layer 220, including an inorganic insulating material and covering the low refractive layer 230.

The second substrate 200 may further include a color conversion layer 250 disposed on the first capping layer 240 and a second capping layer 260 disposed on the first capping layer 240, including an inorganic insulating material and covering the color conversion layer 250.

Referring to FIG. 3, the low refractive layer 230 may include a transparent organic material TOM and hollow silica particles HL dispersed in the transparent organic material TOM.

The transparent organic material TOM may have a refractive index lower than the inorganic insulating material of the first capping layer 240. For example, the refractive index of the transparent organic material TOM may be in a range of about 1.6 to about 1.7. In another embodiment, the refractive index of the transparent organic material TOM may be higher than about 1.7.

The hollow silica particles HL may be particles filled with air. Since a refractive index of air is about 1.0, the higher the content of the hollow silica particles HL in the transparent organic material TOM, the lower the refractive index of the low refractive layer 230.

For example, the refractive index of the low refractive layer 230 may be in a range of about 1.0 to about 1.5.

As illustrated in FIG. 2, according to an embodiment, the low refractive layer 230 may extend not only in the display area DA but also to a portion of the non-display area NDA adjacent to the display area DA.

According to an embodiment, the low refractive layer 230 may not entirely overlap the display area DA and the non-display area NDA of the second support substrate 210 in the third direction DR3. For example, the low refractive layer 230 may overlap only a portion of the non-display area NDA, which is adjacent to the display area DA and the display area DA and may not extend to edges of the second support substrate 210.

Accordingly, side surfaces of the low refractive layer 230 may be spaced from the edges of the second support substrate 210 and may be covered by the first capping layer 240 disposed on the low refractive layer 230. Therefore, a penetration path of oxygen or moisture through the low refractive layer 230 including the transparent organic material TOM may be reduced or delayed.

FIG. 4 is a plan view of the display area DA and the circuit layer 120 of part B illustrated in FIG. 1.

Referring to FIG. 4, the display area DA may include emission areas EA from which light is emitted and a non-emission area NEA between the emission areas EA.

According to embodiments, the emission areas EA may include first emission areas EA1 emitting light of a first wavelength band, second emission areas EA2 emitting light of a second wavelength band lower than the first wavelength band, and third emission areas EA3 emitting light of a third wavelength band lower than the second wavelength band.

For example, the first wavelength band may be in a range of about 600 nm to about 750 nm, and the light of the first wavelength band may be red. The second wavelength band may be in a range of about 480 nm to about 560 nm, and the light of the second wavelength band may be green. The third wavelength band may be in a range of about 370 nm to about 460 nm, and the light of the third wavelength band may be blue.

Accordingly, a unit pixel PX displaying white light may be formed by one or more first emission areas EA1, one or more second emission areas EA2, and one or more third emission areas EA3 adjacent to each other among the emission areas EA.

According to an embodiment, the first emission areas EA1, the second emission areas EA2, and the third emission areas EA3 may be arranged side by side in a second direction DR2.

The third emission areas EA3 may be disposed between the first emission areas EA1 and the second emission areas EA2 in a first direction DR1.

Each of the emission areas EA may have one of rectangular, triangular, rhombic, square, trapezoidal, circular, and oval shapes.

According to an embodiment, the third emission areas EA3 may have a width smaller than the first emission areas EA1 and the second emission areas EA2. Accordingly, in the second direction DR2, a gap between the third emission areas EA3 may be greater than a gap between the first emission areas EA1 and a gap between the second emission areas EA2.

The circuit layer 120 of the first substrate 100 may include light-emitting pixel drivers EPD arranged side by side with each other.

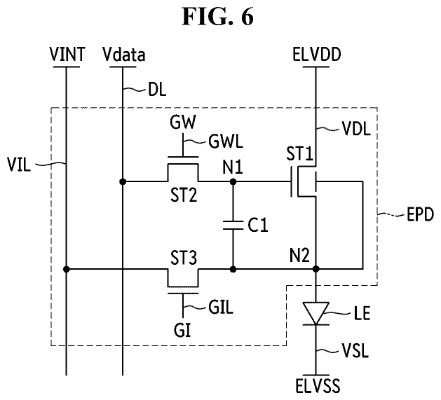

The light-emitting pixel drivers EPD may be respectively electrically connected to light emitting elements LE (see FIG. 6) of the element layer 130 disposed in the emission areas EA.

The light-emitting pixel drivers EPD may include first light-emitting pixel drivers EPD1 electrically connected to light emitting elements LE of the first emission areas EA1, second light-emitting pixel drivers EPD2 electrically connected to light emitting elements LE of the second emission areas EA2, and third light-emitting pixel drivers EPD3 electrically connected to light emitting elements LE of the third emission areas EA3.

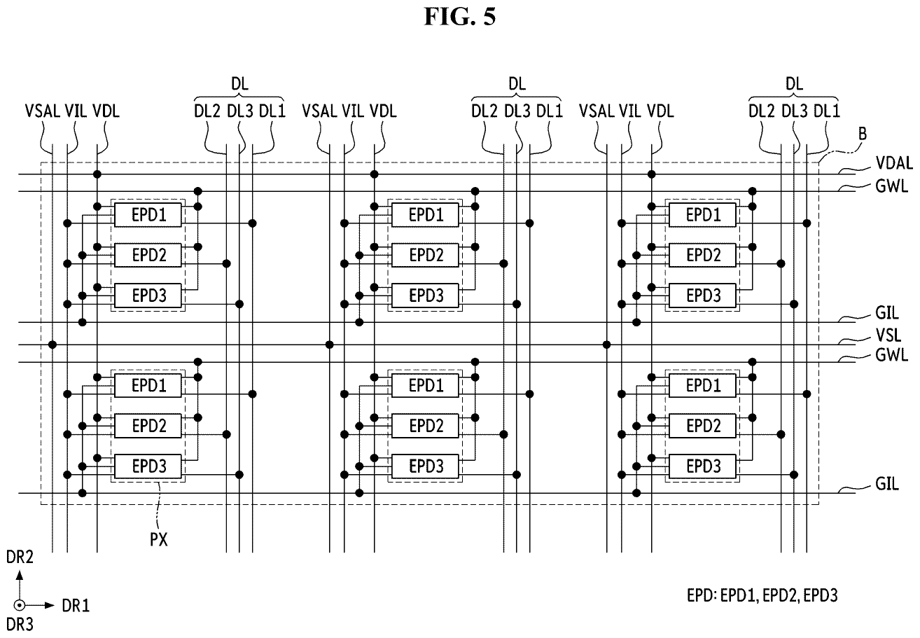

FIG. 5 is a schematic block diagram of the circuit layer 120 of part B illustrated in FIG. 1.

As illustrated in FIG. 5, the circuit layer 120 (see FIG. 2) may include the light-emitting pixel drivers EPD and lines VDL, DL, VIL, GWL and GIL electrically connected to the light-emitting pixel drivers EPD.

The lines VDL, DL, VIL, GWL and GIL may transmit voltages or power and signals to each of the light-emitting pixel drivers EPD.

For example, the circuit layer 120 may further include scan write lines GWL which transmit scan write signals GW (see FIG. 6) to the light-emitting pixel drivers EPD, scan initialization lines GIL which transmit scan initialization signals GI (see FIG. 6) to the light-emitting pixel drivers EPD, data lines DL which transmit data signals Vdata (see FIG. 6) to the light-emitting pixel drivers EPD, initialization voltage lines VIL which transmit initialization voltages VINT (see FIG. 6) to the light-emitting pixel drivers EPD, first power lines VDL which transmit first power ELVDD (see FIG. 6) to the light-emitting pixel drivers EPD, and a second power line VSL which transmits second power ELVSS (see FIG. 6) to the light emitting elements LE (see FIG. 6).

The circuit layer 120 may further include a first power additional line VDAL for reducing the resistance of the first power lines VDL and second power additional lines VSAL for reducing the resistance of the second power line VSL.

The first power additional line VDAL may extend in a direction intersecting the first power lines VDL and may be electrically connected to the first power lines VDL.

The second power additional lines VSAL may extend in a direction intersecting the second power line VSL and may be electrically connected to the second power line VSL.

The data lines DL may include first data lines DL1 which transmit data signals Vdata (see FIG. 6) to the first light-emitting pixel drivers EPD1, second data lines DL2 which transmit data signals Vdata (see FIG. 6) to the second light-emitting pixel drivers EPD2, and third data lines DL3 which transmit data signals Vdata (see FIG. 6) to the third light-emitting pixel drivers EPD3.

FIG. 6 is a schematic diagram of an equivalent circuit of a light-emitting pixel driver EPD of FIG. 5.

Referring to FIG. 6, the light-emitting pixel driver EPD may be electrically connected between first power ELVDD and a light emitting element LE, and the light emitting element LE may be electrically connected between the light-emitting pixel driver EPD and second power ELVSS.

The light emitting element LE may be an organic light emitting diode including an organic light emitting layer, a quantum dot light emitting diode including a quantum dot light emitting layer, a micro-light emitting diode, or an inorganic light emitting diode including an inorganic semiconductor.

The second power ELVSS may have a voltage level lower than the first power ELVDD.

For example, an anode of the light emitting element LE may be electrically connected to the light-emitting pixel driver EPD, and a cathode of the light emitting element LE may be electrically connected to the second power ELVSS.

According to embodiments, the light emitting elements LE of the element layer 130 (see FIG. 2) may emit light of a fourth wavelength band lower than the third wavelength band.

The light-emitting pixel driver EPD may include a first transistor ST1 for generating a driving current of the light emitting element LE, one or more transistors ST2 and ST3 electrically connected to the first transistor ST1, and one or more capacitors C1.

The first transistor ST1 may be electrically connected between a first power line VDL and the light emitting element LE.

A first electrode of the first transistor ST1 may be electrically connected to the first power line VDL.

A second electrode of the first transistor ST1 may be electrically connected to a second node N2 and the anode of the light emitting element LE.

A first gate electrode of the first transistor ST1 may be electrically connected to a first node N1 and a second transistor ST2.

A second gate electrode of the first transistor ST1 may be electrically connected to the second node N2.

The second transistor ST2 may be electrically connected between a data line DL and the first node N1.

A gate electrode of the second transistor ST2 may be electrically connected to a scan write line GWL. For example, the second transistor ST2 may be turned on by a scan write signal GW of the scan write line GWL.

In case that the second transistor ST2 is turned on, a data signal Vdata of the data line DL may be transmitted to the first node N1.

Due to the data signal Vdata transmitted to the first node N1, a voltage difference between the gate electrode of the first transistor ST1 and the first electrode of the first transistor ST1, for example, a gate-source voltage difference, may become a difference voltage between the first power ELVDD and the data signal Vdata and thus become greater than a threshold voltage of the first transistor ST1. Accordingly, the first transistor ST1 may be turned on, and a source-drain current having a magnitude corresponding to the data signal Vdata may be generated between the first electrode and the second electrode of the first transistor ST1. The source-drain current of the first transistor ST1 may be supplied as a driving current to the light emitting element LE.

Accordingly, since the driving current having a magnitude corresponding to the data signal Vdata is supplied to the light emitting element LE, the light emitting element LE may emit light having a luminance corresponding to the data signal Vdata.

A first capacitor C1 may be electrically connected between the first node N1 and the second node N2.

The first capacitor C1 may be charged with the data signal Vdata transmitted to the first node N1 through the turned-on second transistor ST2.

Accordingly, a potential of the first node N1 may be maintained for a period of time due to the voltage that charges the first capacitor C1.

A third transistor ST3 may be electrically connected between an initialization voltage line VIL and the second node N2.

A gate electrode of the third transistor ST3 may be electrically connected to a scan initialization line GIL. For example, the third transistor ST3 may be turned on by a scan initialization signal GI of the scan initialization line GIL.

In case that the third transistor ST3 is turned on, a potential of the second node N2, for example, a potential of the anode of the light emitting element LE, may be initialized to an initialization voltage VINT of the initialization voltage line VIL.

As illustrated in FIG. 6, according to an embodiment, each of the first, second and third transistors ST1, ST2 and ST3 may be an N-type MOSFET. However, the disclosure is not limited thereto, and in another embodiment, at least one of the first, second and third transistors ST1, ST2 and ST3 may be a P-type MOSFET.

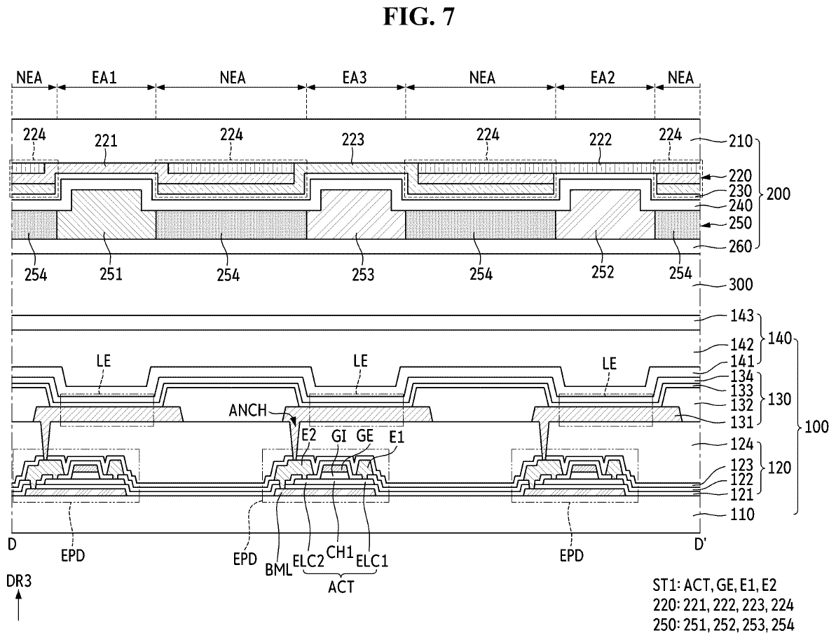

FIG. 7 is a schematic cross-sectional view taken along line D-D′ of FIG. 4 according to embodiments.

Referring to FIG. 7, the display device 10 may include the first substrate 100 and the second substrate 200 facing each other and the filling layer 300 filling a space between the first substrate 100 and the second substrate 200.

The first substrate 100 may include the circuit layer 120 disposed on the first support substrate 110 and including the light-emitting pixel drivers EPD, the element layer 130 disposed on the circuit layer 120 and including the light emitting elements LE disposed in the emission areas EA, and the enclosing layer 140 disposed on the element layer 130.

The enclosing layer 140 may include two or more inorganic insulating layers including an inorganic insulating material and at least one organic insulating layer disposed between the two or more inorganic insulating layers and including an organic insulating material.

The enclosing layer 140 may prevent defects in the circuit layer 120 or the element layer 130 caused by foreign substances and prevent oxygen or moisture from penetrating into the circuit layer 120 or the element layer 130.

The first support substrate 110 may include the display area DA (see FIG. 1) and the non-display area NDA (see FIG. 1).

The display area DA may include the emission areas EA (EA1, EA2 and EA3 in FIG. 4) arranged side by side and the non-emission area NEA between the emission areas EA.

For example, a width of the non-display area NDA of the second support substrate 210 may be equal to or less than a width of the non-display area NDA of the first support substrate 210.

The circuit layer 120 may include a buffer layer 121 disposed on the first support substrate 110, a first interlayer insulating layer 122 disposed on the buffer layer 121, a second interlayer insulating layer 123 disposed on the first interlayer insulating layer 122, and a planarization layer 124 disposed on the second interlayer insulating layer 123.

Each of the buffer layer 121, the first interlayer insulating layer 122, and the second interlayer insulating layer 123 may include an inorganic insulating material.

The planarization layer 124 may include an organic insulating material.

The circuit layer 120 may include the light-emitting pixel drivers EPD which transmit driving currents to the light emitting elements LE.

Each of the light-emitting pixel drivers EPD may include two or more transistors ST1, ST2 and ST3 (see FIG. 6).

The first transistor ST1 of each of the light-emitting pixel drivers EPD may include an active layer ACT disposed on the buffer layer 121, a gate electrode GE disposed on a gate insulating layer GI covering a channel portion CH1 of the active layer ACT, and a first electrode E1 and a second electrode E2 disposed on the first interlayer insulating layer 122 covering the active layer ACT and the gate electrode GE.

At least the channel portion CH1 of the active layer ACT may overlap a light blocking layer BML on the first support substrate 110 in the third direction DR3.

The buffer layer 121 may cover the light blocking layer BML.

The active layer ACT may include the channel portion CH1, a first electrode portion ELC1 connected to a side of the channel portion CH1, and a second electrode portion ELC2 connected to another side of the channel portion CH1.

The first electrode E1 may be electrically connected to the first electrode portion ELC1 of the active layer ACT through a hole penetrating the first interlayer insulating layer 122.

The second electrode E2 may be electrically connected to the second electrode portion ELC2 of the active layer ACT through a hole penetrating the first interlayer insulating layer 122.

The second electrode E2 may be electrically connected to the light blocking layer BML through a hole penetrating the first interlayer insulating layer 122 and the buffer layer 121.

Since the light blocking layer BML faces a back surface of the active layer ACT, a portion of the active layer ACT which is adjacent to the light blocking layer BML may be activated relatively weakly compared with another portion adjacent to the gate electrode GE according to the potential of the light blocking layer BML which is the same as the potential of the second electrode E2.

The second interlayer insulating layer 123 may cover the first interlayer insulating layer 122, the first electrode E1, and the second electrode E2.

Each of the buffer layer 121, the gate insulating layer GI, the first interlayer insulating layer 122, and the second interlayer insulating layer 123 may include an inorganic insulating material.

The element layer 130 may be disposed on the planarization layer 124.

The element layer 130 may include the light emitting elements LE disposed in the emission areas EA. The light emitting elements LE may emit light of the fourth wavelength band.

Each of the light emitting elements LE may include a structure in which a light emitting layer 133 is disposed between an anode 131 and a cathode 134 facing each other.

For example, the element layer 130 may include anodes 131 disposed in the emission areas EA, a pixel defining layer 132 disposed in the non-emission area NEA and covering edges of the anodes 131, the light emitting layer 133 disposed on the anodes 131 and the pixel defining layer 132, and the cathode 134 disposed on the light emitting layer 133.

In another embodiment, light emitting layers 133 may be disposed in the emission areas EA, respectively.

The anodes 131 may be electrically connected to the light-emitting pixel drivers EPD through anode connection holes ANCH.

For example, the anodes 131 may be electrically connected to the second electrodes E2 of the first transistors ST1 of the light-emitting pixel drivers EPD through the anode connection holes ANCH.

The anode connection holes ANCH may penetrate the planarization layer 124 and the second interlayer insulating layer 123.

The enclosing layer 140 may include a first enclosing layer 141 disposed on the element layer 130 and including an inorganic insulating material, a second enclosing layer 142 disposed on the first enclosing layer 141 and including an organic insulating material, and a third enclosing layer 143 disposed on the second enclosing layer 142 and including an inorganic insulating material.

The second substrate 200 may include the color filter layer 220 disposed on the second support substrate 210, the low refractive layer 230 disposed on a portion of the color filter layer 220, the first capping layer 240 covering the low refractive layer 230, the color conversion layer 250 disposed on the first capping layer 240, and the second capping layer 260 covering the color conversion layer 250.

The second support substrate 210 may include the display area DA (see FIG. 1) and the non-display area NDA (see FIG. 1).

For example, the width of the non-display area NDA of the second support substrate 210 may be equal to or less than the width of the non-display area NDA of the first support substrate 210.

In a direction (e.g., a third direction DR3) in which light of the display device 10 is emitted, the low refractive layer 230 may be disposed on the color conversion layer 250, the color filter layer 220 may be disposed on the low refractive layer 230, and the second support substrate 210 may be disposed on the color filter layer 220. Accordingly, light emitted from the light emitting elements LE of the element layer 130 may pass through the color conversion layer 250, the low refractive layer 230, the color filter layer 220 and the second support substrate 210 and be emitted to the outside.

The color conversion layer 250 may convert the wavelength band of light emitted from the light emitting elements LE of some emission areas EA of the element layer 130.

For example, the color conversion layer 250 may convert light emitted from a light emitting element LE of a first emission area EA1 from the fourth wavelength band to the first wavelength band, may convert light emitted from a light emitting element LE of a second emission area EA2 from the fourth wavelength band to the second wavelength band, and may transmit and scatter light emitted from a light emitting element LE of a third emission area EA3.

The color filter layer 220 may transmit light of some wavelength bands among light emitted from the color conversion layer 250 in the emission areas EA.

For example, the color filter layer 220 may transmit light of the first wavelength band in the first emission area EA1, transmit light of the second wavelength band in the second emission area EA2, and transmit light of the third wavelength band in the third emission area EA3.

For example, the color conversion layer 250 may include a first color conversion portion 251 disposed in the first emission area EA1, a second color conversion portion 252 disposed in the second emission area EA2, a light transmitting portion 253 disposed in the third emission area EA3, and a partition wall 254 disposed in the non-emission area NEA.

The first color conversion portion 251 may convert light of the fourth wavelength band emitted from the light emitting element LE of the first emission area EA1 into light of the first wavelength band.

The first color conversion portion 251 may be a cured product of a first ink material including a base resin and first color conversion particles dispersed in the base resin. The first color conversion particles may convert light of the fourth wavelength band into light of the first wavelength band.

The second color conversion portion 252 may convert light of the fourth wavelength band emitted from the light emitting element LE of the second emission area EA2 into light of the second wavelength band.

The second color conversion portion 252 may be a cured product of a second ink material including a base resin and second color conversion particles dispersed in the base resin. The second color conversion particles may convert light of the fourth wavelength band into light of the second wavelength band.

The light transmitting portion 253 may transmit and scatter light of the fourth wavelength band emitted from the light emitting element LE of the third emission area EA3.

The light transmitting portion 253 may include a base resin and scattering particles dispersed in the base resin.

The scattering particles may be metal oxide particles or organic particles.

The metal oxide particles may be at least one of titanium oxide (TiO₂), zirconium oxide (ZrO₂), aluminum oxide (Al₂O₃), indium oxide (In₂O₃), zinc oxide (ZnO), and tin oxide (SnO₂).

The organic particles may be an acrylic resin or a urethane resin.

Each of the first color conversion portion 251 and the second color conversion portion 252 may further include scattering particles dispersed in the base resin.

Each of the first color conversion particles and the second color conversion particles may be at least one of a quantum dot, a quantum rod, and a phosphor.

The quantum dot may include at least one of group IV nanocrystals, group II-VI compound nanocrystals, group III-V compound nanocrystals, group IV-VI nanocrystals, and a combination thereof.

The first color conversion portion 251, the second color conversion portion 252, and the light transmitting portion 253 may include a same base resin or may include different base resins.

The partition wall 254 may be disposed between the first color conversion portion 251, the second color conversion portion 252, and the light transmitting portion 253.

The partition wall 254 may include an organic material.

The color conversion layer 250 may be disposed in the display area DA between the first capping layer 240 and the second capping layer 260 and thus may be sealed with a bonding structure of inorganic insulating materials. Accordingly, the penetration of oxygen or moisture through the color conversion layer 260 may be reduced or delayed.

The low refractive layer 230 may overlap the emission areas EA of the display area DA in the third direction DR3.

The low refractive layer 230 may include the hollow silica particles HL (see FIG. 3) dispersed in the transparent organic material TOM (see FIG. 3).

Therefore, the low refractive layer 230 may have a refractive index in a range of about 1.0 to about 1.5. For example, the low refractive layer 230 may have a refractive index in a range of about 1.1 to about 1.4.

Since the light emission efficiency of the second substrate 200 can be improved by the low refractive layer 230, the luminance and display quality of the display device 10 may be improved.

The color filter layer 220 may include a first filter portion 221 disposed in the first emission area EA1 and transmitting light of the first wavelength band, a second filter portion 222 disposed in the second emission area EA2 and transmitting light of the second wavelength band, a third filter portion 223 disposed in the third emission area EA3 and transmitting light of the third wavelength band, and a light blocking portion 224 disposed in the non-emission area NEA and the non-display area NDA (see FIG. 1) and blocking light.

Each of the first filter portion 221, the second filter portion 222, and the third filter portion 223 may include a colorant such as a dye or pigment. The colorant may be a material that absorbs light of wavelength bands other than a wavelength band.

For example, the first filter portion 221 may transmit light of the first wavelength band by including a colorant that absorbs light of wavelength bands other than the first wavelength band among light transmitted through the color conversion layer 250.

The second filter portion 222 may transmit light of the second wavelength band by including a colorant that absorbs light of wavelength bands other than the second wavelength band among the light transmitted through the color conversion layer 250.

The third filter portion 223 may transmit light of the third wavelength band by including a colorant that absorbs light of wavelength bands other than the third wavelength band among the light transmitted through the color conversion layer 250.

The light blocking portion 224 may include a structure in which two or more of the first filter portion 221, the second filter portion 222, and the third filter portion 223 are stacked.

In another embodiment, the light blocking portion 224 may include a material that absorbs light, such as a black matrix material.

The filling layer 300 may fill the space between the first substrate 100 and the second substrate 200.

The filling layer 300 may be disposed between the enclosing layer 140 of the first substrate 100 and the second capping layer 260 of the second substrate 200.

The filling layer 300 may include an organic material having light transmitting properties and adhesiveness.

For example, the filling layer 300 may include a Si-based organic material or an epoxy-based organic material.

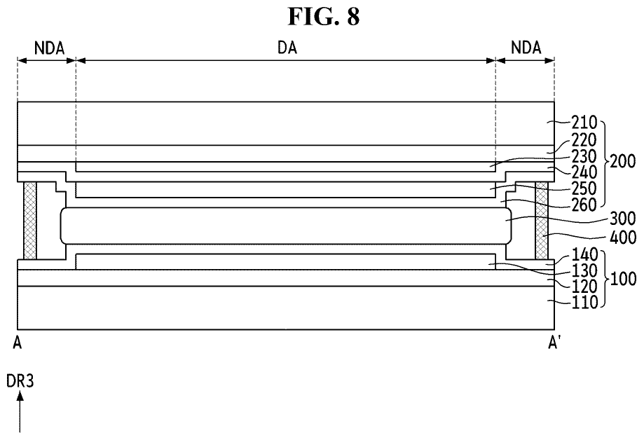

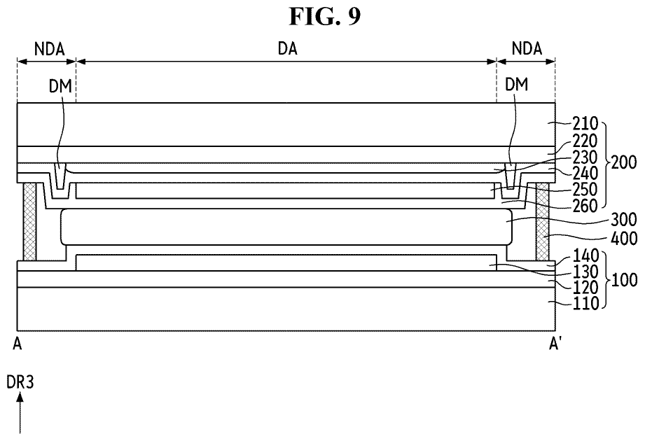

FIGS. 8 and 9 are schematic cross-sectional views taken along line A-A′ of FIG. 1 according to embodiments.

A display device 10 of an embodiment illustrated in FIG. 8 may be substantially the same as the display device 10 of the embodiments illustrated in FIGS. 1 through 7 except that a low refractive layer 230 may not overlap a non-display area NDA and overlap only a display area DA in the third direction DR3. Therefore, redundant descriptions will be omitted below.

According to an embodiment of FIG. 8, the light emission efficiency of emission areas EA may be improved by the low refractive layer 230, and a distance from each side surface of a second support substrate 210 to the low refractive layer 230 may be relatively long. Therefore, a penetration path of oxygen or moisture through the low refractive layer 230 may be further delayed or reduced.

A display device 10 of an embodiment illustrated in FIG. 9 may be substantially the same as the display devices 10 of the embodiments illustrated in FIGS. 1 through 8 except that the display device 10 in FIG. 9 may further include a frame-shaped dam portion DM disposed on a color filter layer 220 in a non-display area NDA and surrounding a display area DA in a plan view. Therefore, redundant descriptions will be omitted below.

According to embodiment of FIG. 9, a low refractive layer 230 may be disposed only in an area surrounded by the dam portion DM in a plan view.

Accordingly, since the placement range of the low refractive layer 230 can be limited by the dam portion DM, the possibility that the low refractive layer 230 will be disposed adjacent to edges of a second support substrate 210 due to the spread of a material of the low refractive layer 230 to a surrounding area may be eliminated. Therefore, process defects in a process of placing the low refractive layer 230 may be reduced, thereby improving the ease and simplicity of the process of placing the low refractive layer 230.

As described above, according to embodiments, the low refractive layer 230 may be disposed only in a portion of the non-display area NDA which is adjacent to the display area DA and in the display area DA. Therefore, the low refractive layer 230 may be entirely covered by a first capping layer 240 disposed on the entire surface of the second support substrate 210. For example, side surfaces of the low refractive layer 230 may not be exposed to the outside.

Therefore, the penetration of oxygen or moisture through a transparent organic material TOM (see FIG. 3) of the low refractive layer 230 may be reduced or delayed. As a result, the lifespan and display quality of the display device 10 may be improved.

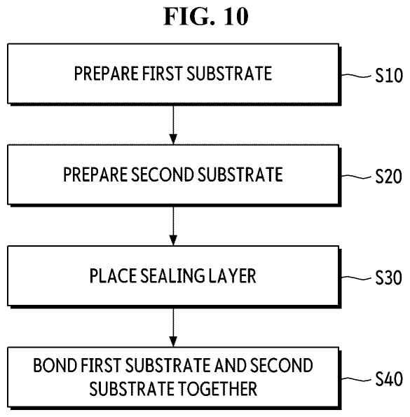

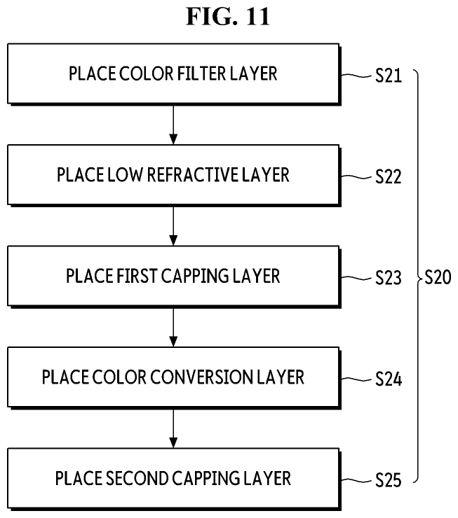

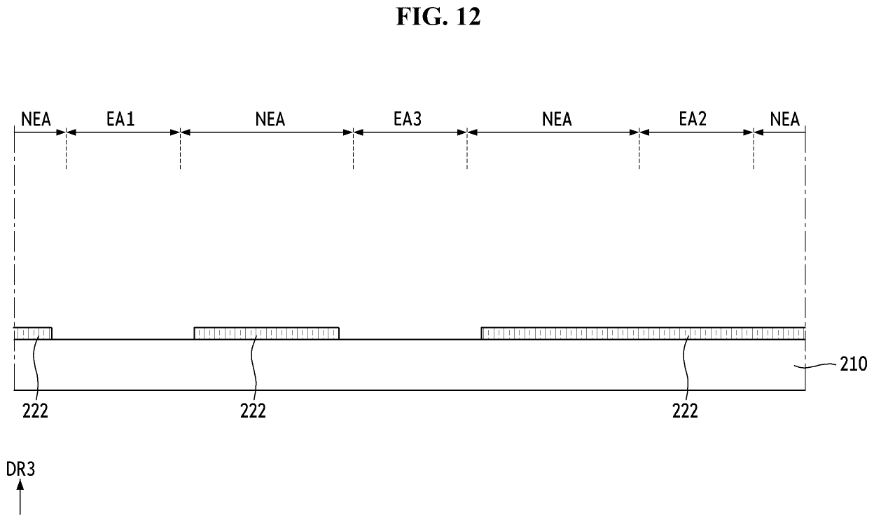

FIG. 10 is a flowchart illustrating a method of manufacturing a display device according to embodiments. FIG. 11 is a flowchart illustrating an operation of preparing a second substrate in FIG. 10 according to embodiments. FIGS. 12, 13, 14, 15, 16, 17, 18, and 19 are schematic diagrams illustrating some operations of FIGS. 10 and 11.

Referring to FIG. 10, the method of manufacturing the display device 10 according to embodiments may include preparing a first substrate 100 (operation S10), preparing a second substrate 200 (operation S20), placing a sealing layer 400 on the first substrate 100 or the second substrate 200 (operation S30), and bonding the first substrate 100 and the second substrate 200 together using the sealing layer 400 (operation S40).

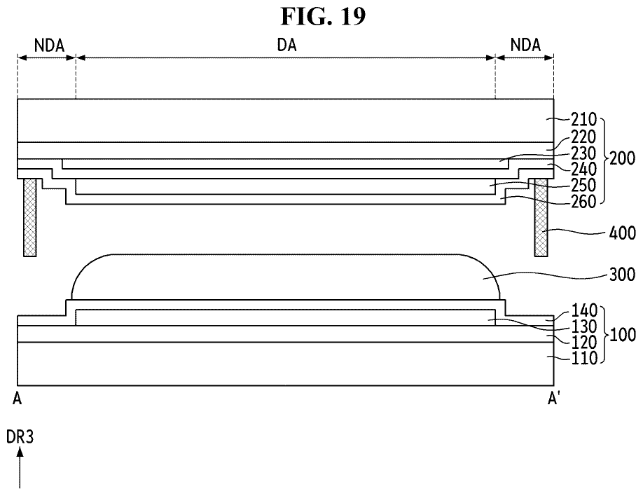

As illustrated in FIG. 19, the preparing of the first substrate 100 (operation S10) may include placing a circuit layer 120 on a first support substrate 110, placing an element layer 130 on the circuit layer 120, and placing an enclosing layer 140 on the element layer 130.

Referring to FIG. 11, the preparing of the second substrate 200 (operation S20) according to embodiments may include placing a color filter layer 220 on a second support substrate 210 (operation S21), placing a low refractive layer 230, which overlaps emission areas EA, on a portion of the color filter layer 220 (operation S22), and placing a first capping layer 240 which covers the low refractive layer 230 by stacking an inorganic insulating material on the color filter layer 220 (operation S23).

The preparing of the second substrate 200 (operation S20) according to embodiments may further include placing a color conversion layer 250 on the first capping layer 240 (operation S24) and placing a second capping layer 260 which covers the color conversion layer 250 by stacking an inorganic insulating material on the first capping layer 240 (operation S25).

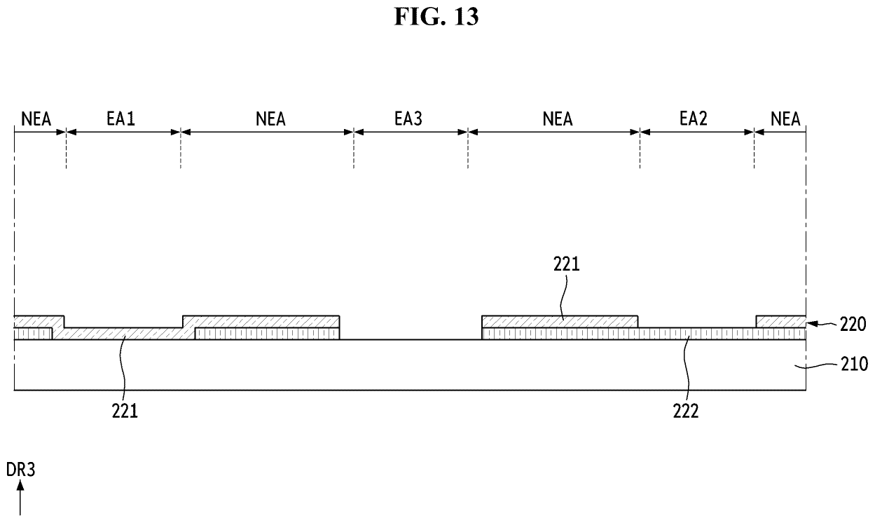

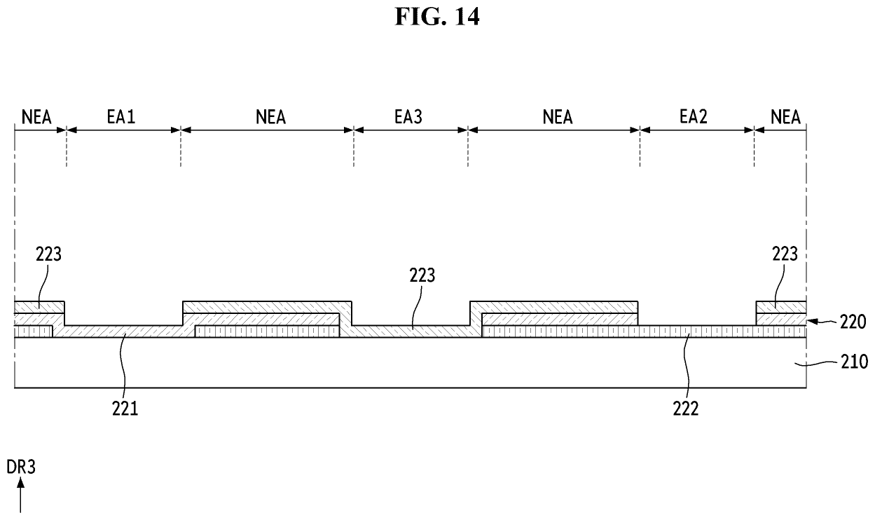

As illustrated in FIGS. 12, 13 and 14, the placing of the color filter layer 220 (operation S21) may include placing a second filter portion 222 (see FIG. 12), placing a first filter portion 221 (see FIG. 13), and placing a third filter portion 223 (see FIG. 14).

As illustrated in FIG. 12, the second filter portion 222 may be placed on the second support substrate 210 in a second emission area EA2.

In order to provide a light blocking portion 224 (see FIG. 7), the second filter portion 222 may be further placed in a non-emission area NEA and a non-display area NDA (see FIG. 1).

As illustrated in FIG. 13, the first filter portion 221 may be placed on the second support substrate 210 in a first emission area EA1.

In order to provide the light blocking portion 224 (see FIG. 7), the first filter portion 221 may be further placed on the second filter portion 222 in the non-emission area NEA and the non-display area NDA (see FIG. 1).

As illustrated in FIG. 14, the third filter portion 223 may be placed on the second support substrate 210 in a third emission area EA3.

In order to provide the light blocking portion 224 (see FIG. 7), the third filter portion 223 may be further placed on the first filter portion 221 in the non-emission area NEA and the non-display area NDA (see FIG. 1).

As a result, in the non-emission area NEA and the non-display area NDA, the light blocking portion 224 may be provided in a structure in which the first filter portion 221, the second filter portion 222, and the third filter portion 223 are stacked.

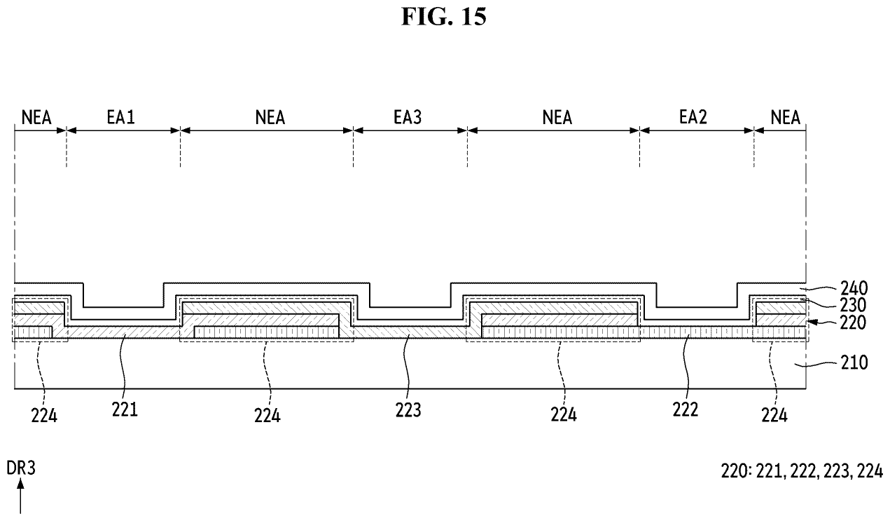

As illustrated in FIG. 15, in the placing of the low refractive layer 230 (operation S22), the low refractive layer 230 may overlap a display area DA in the third direction DR3 including the emission areas EA (EA1, EA2 and EA3) and the non-emission area NEA. The placing of the low refractive layer 230 (operation S22) according to embodiments will be described in detail below.

In the placing of the first capping layer 240 (operation S23), the first capping layer 240 may include an inorganic insulating material that covers the low refractive layer 230.

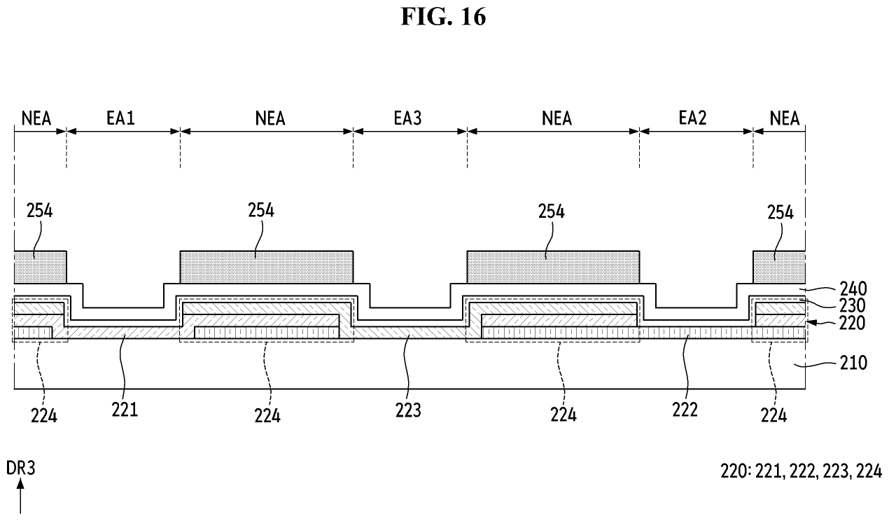

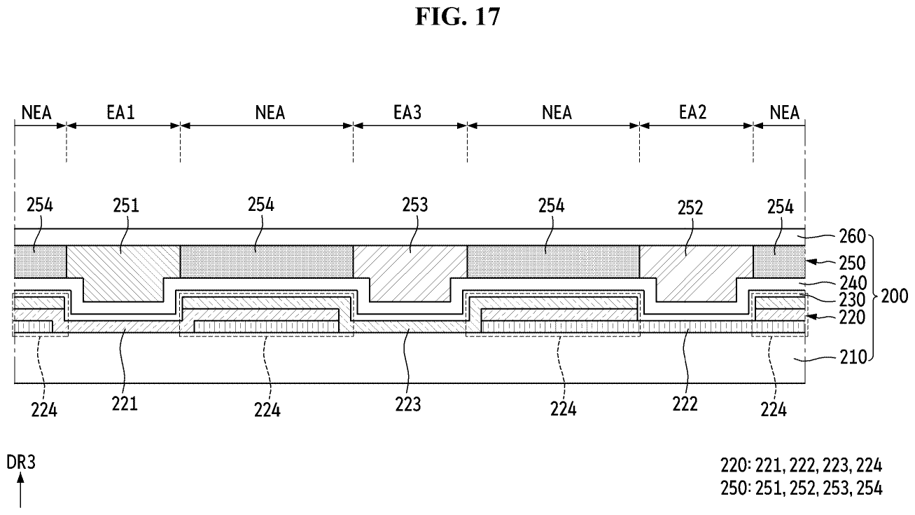

As illustrated in FIGS. 16 and 17, the placing of the color conversion layer 250 (operation S24) may include placing a partition wall 254 on the first capping layer 240 in the non-emission area NEA and placing a first color conversion portion 251 in the first emission area EA1, placing a second color conversion portion 252 in the second emission area EA2 and placing a light transmitting portion 253 in the third emission area EA3.

Referring to FIG. 16, in the placing of the partition wall 254, the partition wall 254 may be placed by partially removing an organic material on the first capping layer 240.

Referring to FIG. 17, the placing of the first color conversion portion 251, the second color conversion portion 252, and the light transmitting portion 253 may include a process of placing the first color conversion portion 251 by ejecting a first ink material into the first emission area EA1 surrounded by the partition wall 154 and curing the first ink material, a process of placing the second color conversion portion 252 by ejecting a second ink material into the second emission area EA2 surrounded by the partition wall 154 and curing the second ink material, and a process of placing the light transmitting portion 253 by curing a light transmitting material accommodated in the third emission area EA3 surrounded by the partition wall 154.

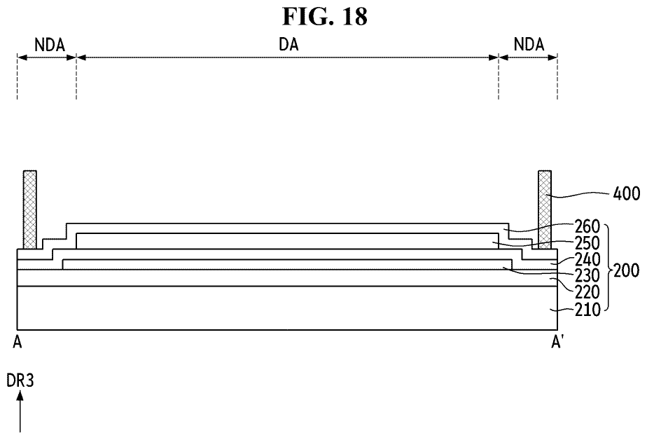

Referring to FIG. 18, the placing of the sealing layer 400 (operation S30) may include a process of placing a sealing material on the second capping layer 260 in the non-emission area NEA of at least one of the first substrate 100 and the second substrate 200.

The sealing layer 400 may be spaced apart from the display area DA and placed in a frame shape surrounding the display area DA.

Referring to FIG. 19, the method of manufacturing the display device 10 according to embodiments may further include placing a filling layer 300 on one of the first substrate 100 and the second substrate 200 before the bonding of the first substrate 100 and the second substrate 200 (operation S40 of FIG. 10).

As illustrated in FIG. 2, in the bonding of the first substrate 100 and the second substrate 200 (operation S40), a space between the first substrate 100 and the second substrate 200 bonded to each other through the sealing layer 400 may be filled with the filling layer 300.

The low refractive layer 230 may include hollow silica particles HL (see FIG. 3) dispersed in a transparent organic material TOM (see FIG. 3), and the higher the content of the hollow silica particles HL in the low refractive layer 230, the lower the refractive index of the low refractive layer 230.

For example, if the low refractive layer 230 further contains a photoinitiator, etc. for an exposure process, it may be disadvantageous in lowering the refractive index.

Therefore, it may be difficult to perform an exposure process to the low refractive layer 230 to partially place the low refractive layer 230.

Hence, the following embodiments provide methods of manufacturing a display device 10 in which a low refractive layer 230 can be partially placed without performing an exposure process on the low refractive layer 230.

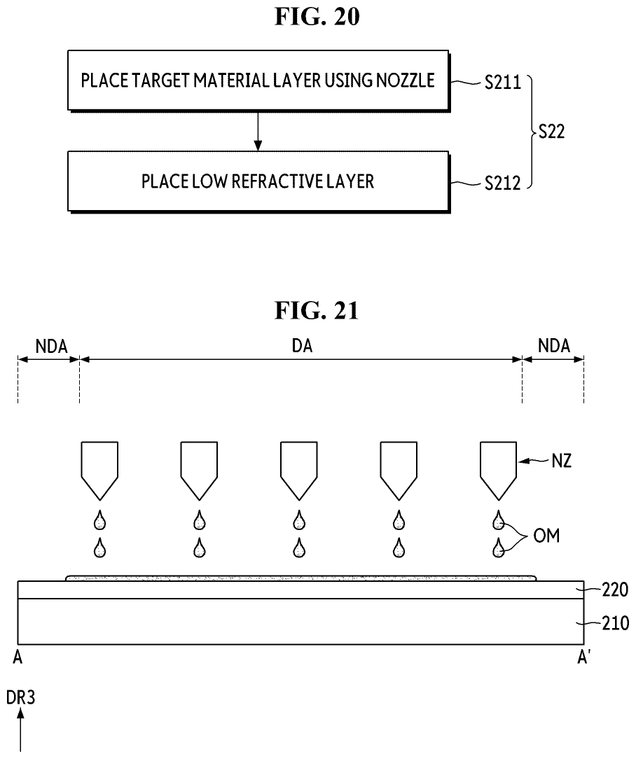

FIG. 20 is a flowchart illustrating the placing of the low refractive layer 230 (operation S22) in FIG. 11 according to an embodiment. FIGS. 21, 22 and 23 are schematic diagrams illustrating operations of FIG. 20.

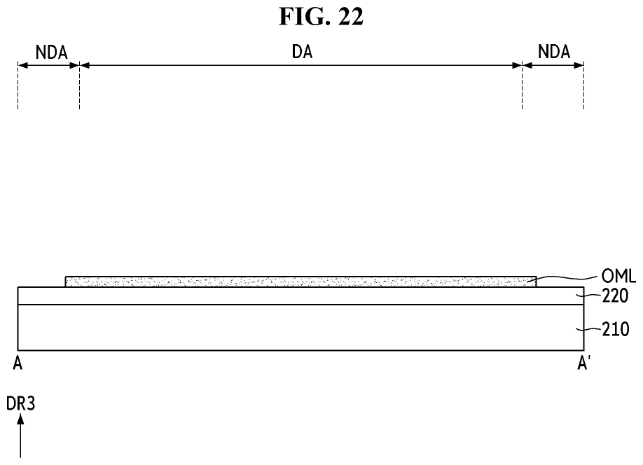

According to an embodiment of FIG. 20, the placing of the low refractive layer 230 (operation S22) may include placing a target material layer OML (see FIG. 22) using a nozzle NZ (see FIG. 21) (operation S211) and placing a low refractive layer 230 by curing the target material layer OML (see FIG. 22) (operation S212).

As illustrated in FIGS. 21 and 22, in the placing of the target material layer OML (operation S211), the target material layer OML may be placed on a portion of a color filter layer 220 by dropping a target material OM on the portion of the color filter layer 220 through the nozzle NZ.

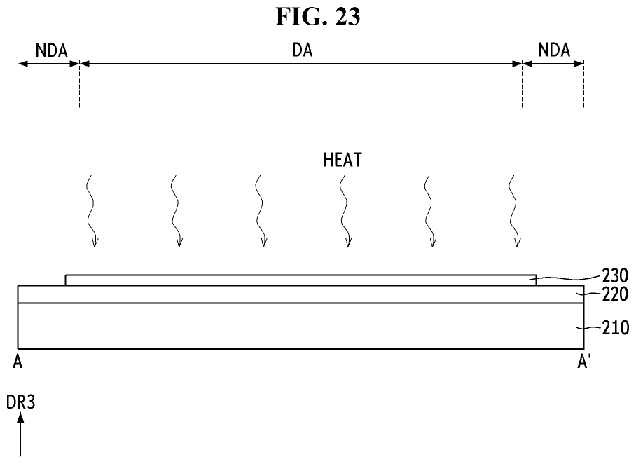

As illustrated in FIG. 23, in the placing of the low refractive layer 230 (operation S212), the low refractive layer 230 may be prepared by curing the target material layer OML placed on the portion of the color filter layer 220 by performing low-temperature heat treatment HEAT.

During the process of curing the target material layer OML, a heat treatment temperature may be a low temperature less than or equal to about 130° C. For example, the heat treatment temperature may be about 110° C.

As described above, the embodiment illustrated in FIGS. 20, 21, 22 and 23 has an advantage in that the low refractive layer 230 may be placed in a portion without a separate mask process by placing the target material layer OML in the portion using the nozzle NZ. On the other hand, since the target material layer OML is placed in a portion in a liquid state in order to use the nozzle NZ, it may be difficult to place the low refractive layer 230 in a specific area. For example, even if the target material layer OML is dropped in a specific area, the target material layer OML in the liquid state may be irregularly spread. Therefore, edges of the low refractive layer 230 may be partially deformed into a wave shape different from the shape in which the target material layer OML is dropped.

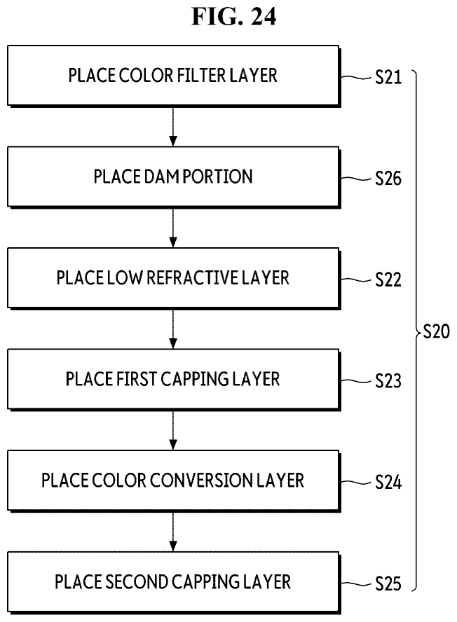

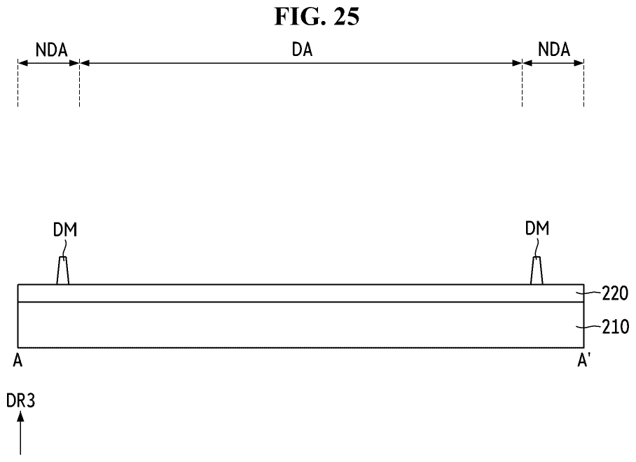

FIG. 24 is a flowchart illustrating an operation of preparing a second substrate according to an embodiment. FIGS. 25, 26, and 27 are schematic diagrams illustrating operations of FIGS. 20 and 24.

The embodiment of FIG. 24 may be substantially the same as the embodiment of FIG. 11 except that the operation of preparing the second substrate 200 (operation S20) may further include placing a dam portion DM (see FIG. 25) (operation S26) before placing a low refractive layer 230 (operation S22). Therefore, redundant descriptions will be omitted below.

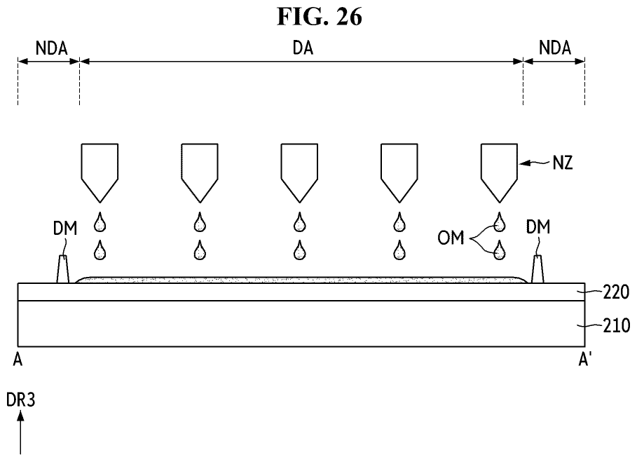

The embodiment of FIG. 24 may be substantially the same as the embodiment of FIG. 20 except that the placing of the low refractive layer 230 (operation S22) may further include spreading a target material OM (see FIG. 26) before curing a target material layer OML (operation S212 of FIG. 20). Therefore, redundant descriptions will be omitted below.

As illustrated in FIG. 25, in the placing of the dam portion DM (operation S26), the dam portion DM may be placed by partially removing an organic material on a color filter layer 220.

The dam portion DM may be placed on the color filter layer 220 in the non-display area NDA, may be spaced apart from a display area DA, and may be in the form of a frame surrounding the display area DA in a plan view.

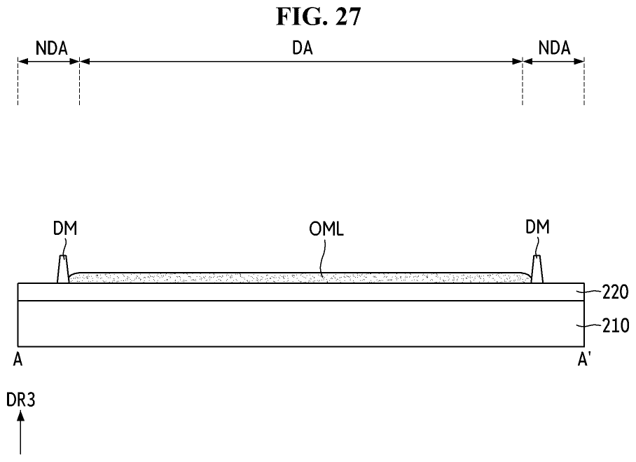

As illustrated in FIG. 26, in the placing of the target material layer OML (see FIG. 27) (operation S211 of FIG. 20), the target material OM may be dropped into an area surrounded by the dam portion DM on the color filter layer 220 through a nozzle NZ.

As illustrated in FIG. 27, the target material OM dropped onto the color filter layer 220 may be evenly spread in the area surrounded by the dam portion DM over time. Accordingly, the target material layer OML may be placed.

The target material layer OML may be placed only in the area surrounded by the dam portion DM.

As illustrated in FIGS. 9 and 23, the low refractive layer 230 may be prepared by curing the target material layer OML which is placed on a portion of the color filter layer 220 and surrounded by the dam portion DM.

According to the embodiment of FIGS. 24-27, there are disadvantages in that a mask process for preparing the dam portion DM may be added and in that thinning and structural simplification may be limited by the placement of the dam portion DM. On the other hand, since it can be prevented from spreading the target material layer OML out of the dam portion DM, placement defects of the low refractive layer 230 may be reduced. As a result, the quality uniformity of a display device 10 may be improved.

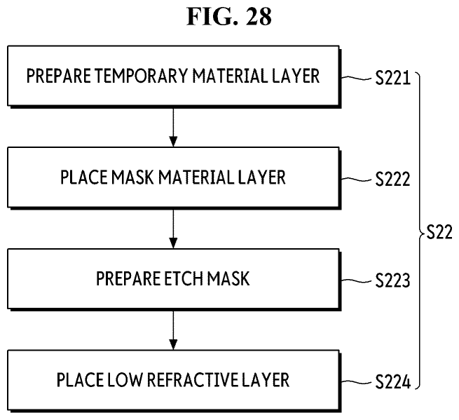

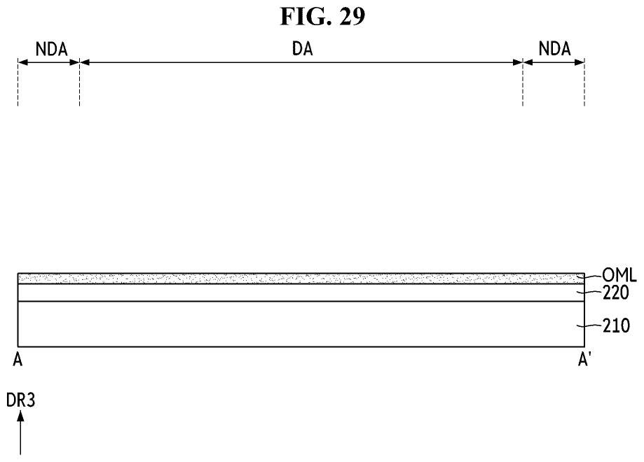

FIG. 28 is a flowchart illustrating the placing of the low refractive layer 230 (operation S22) in FIG. 11 according to an embodiment. FIGS. 29, 30, 31, 32, and 33 are schematic diagrams illustrating operations of FIG. 28.

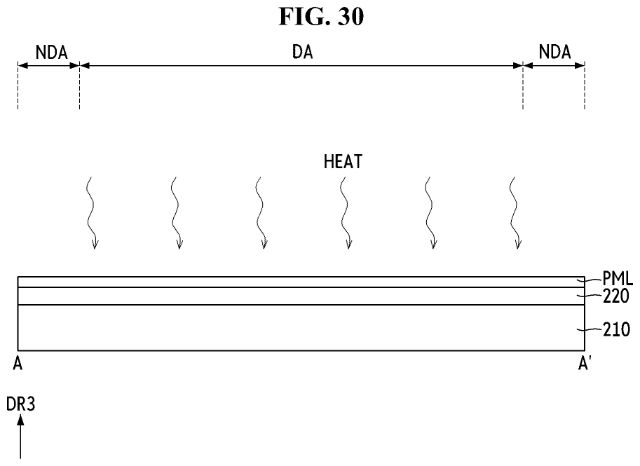

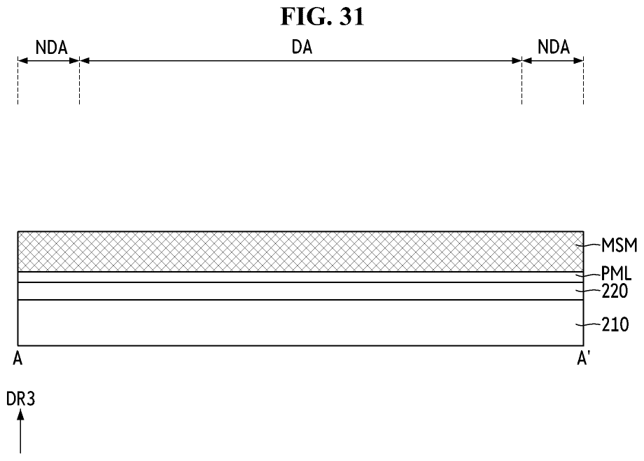

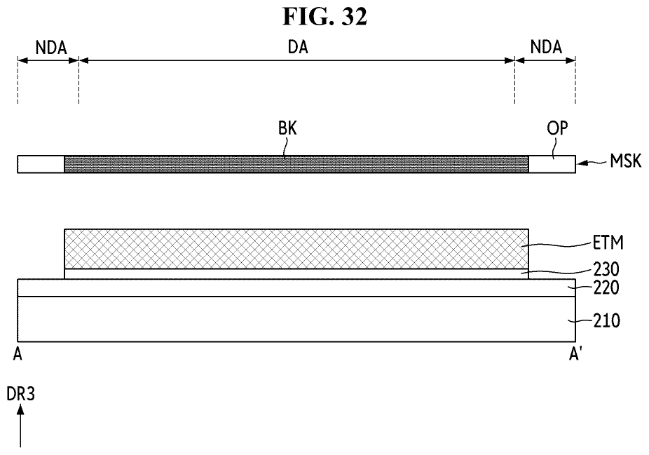

According to the embodiment of FIG. 28, the placing of the low refractive layer 230 (operation S22) may include preparing a temporary material layer PML (see FIG. 30) by curing a target material layer OML (see FIG. 29) on a color filter layer 220 (operation S221), placing a mask material layer MSM (see FIG. 31) on the temporary material layer PML (operation S222), preparing an etch mask ETM (see FIG. 32) by removing the mask material layer MSM except for a portion overlapping at least a display area DA in the third direction DR3 (operation S223), and placing a low refractive layer 230 by partially removing the temporary material layer PML according to the etch mask ETM (operation S224).

As illustrated in FIG. 29, in the preparing of the temporary material layer PML (operation S221), the target material layer OML may be placed by applying a target material onto an entire area of the color filter layer 220. The target material layer OML may be placed on the color filter layer 220 in the display area DA and a non-display area NDA of a second support substrate 210.

As illustrated in FIG. 30, in the preparing of the temporary material layer PML (operation S221), the temporary material layer PML may be placed by performing low-temperature heat treatment HEAT on the target material layer OML (see FIG. 29).

A heat treatment temperature may be a low temperature less than or equal to about 130° C. For example, the heat treatment temperature may be about 110° C.

As illustrated in FIG. 31, in the placing of the mask material layer MSM (operation S222), the mask material layer MSM may be placed by stacking a mask material on an entire area of the temporary material layer PML.

As illustrated in FIG. 32, in the preparing of the etch mask ETM (operation S223), the etch mask ETM may be placed on a portion of the color filter layer 220 by partially exposing the mask material layer MSM through an exposure mask MSK and developing the mask material layer MSM.

For example, the exposure mask MSK may include a blocking portion BK which faces at least the display area DA of the second support substrate 210 and blocks light and an opening OP which is a portion other than the blocking portion BK and transmits light.

The blocking portion BK may also face a portion of the non-display area NDA which is adjacent to the display area DA of the second support substrate 210.

Accordingly, the etch mask ETM may overlap at least the display area DA of the second support substrate 210 in the third direction DR3.

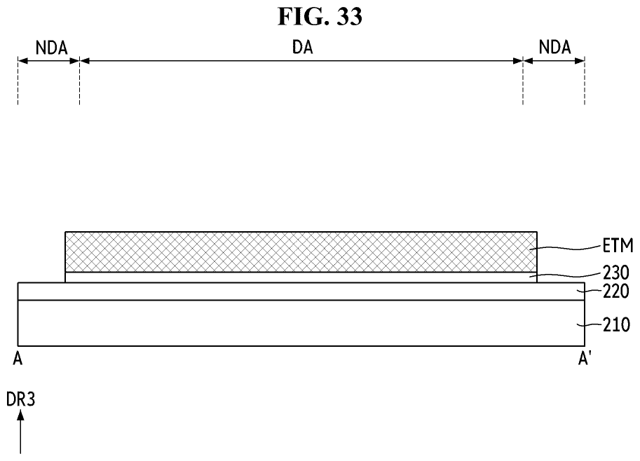

As illustrated in FIG. 33, in the placing of the low refractive layer 230 (operation S224), the low refractive layer 230 may be prepared by removing a portion of the temporary material layer PML which is not covered by the etch mask ETM.

According to the embodiment of FIGS. 28-33, compared with the embodiment of FIG. 20, it may have disadvantages in that a mask process may be added and that a portion of the color filter layer 220 which is not covered by the low refractive layer 230 may be exposed to an etching process and thus damaged. On the other hand, since the low refractive layer 230 can be placed with a relatively uniform thickness, process defects in the placing of the low refractive layer 230 (operation S22) may be reduced.

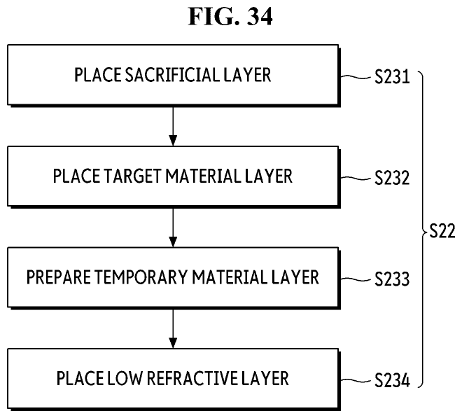

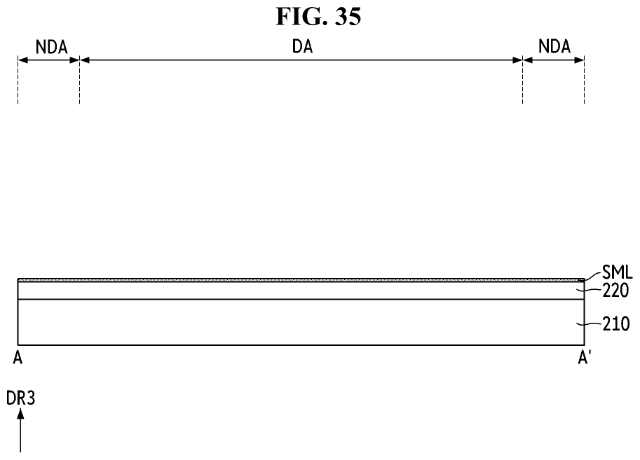

FIG. 34 is a flowchart illustrating the placing of the low refractive layer 230 (operation S22) in FIG. 11 according to an embodiment. FIGS. 35, 36, 37, 38, and 39 are schematic diagrams illustrating operations of FIG. 34.

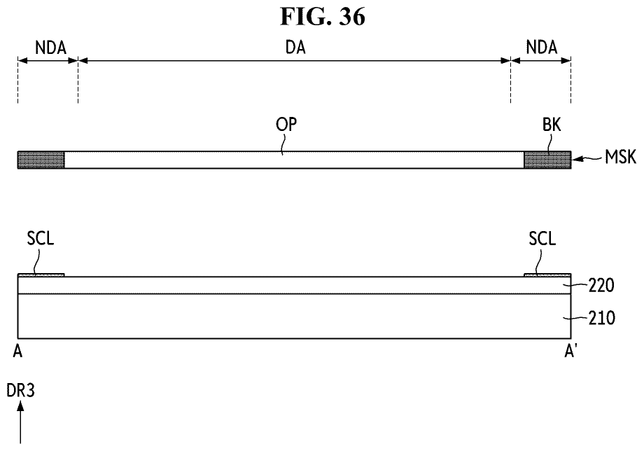

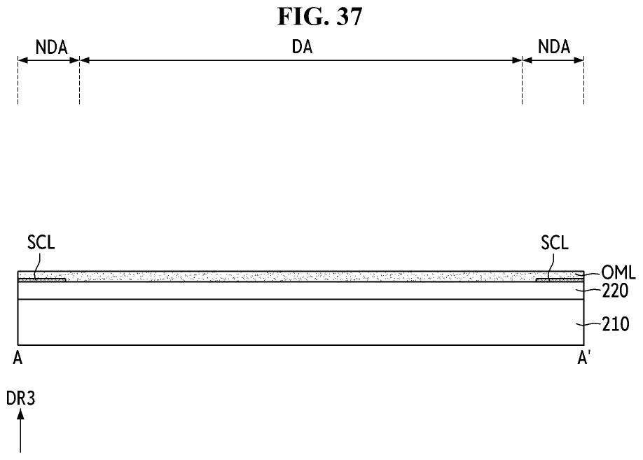

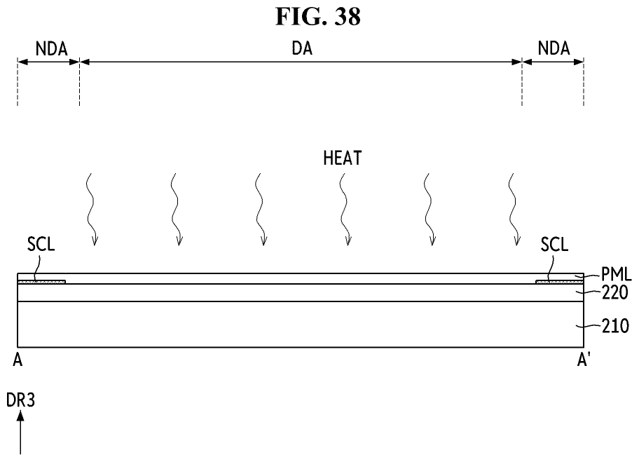

According to the embodiment of FIG. 34, the placing of the low refractive layer 230 (operation S22) may include placing a sacrificial layer SCL (see FIG. 36) by removing a portion of a sacrificial material layer SML (see FIG. 35), which overlaps a display area DA in the third direction, on a color filter layer 220 (operation S231), placing a target material layer OML (see FIG. 37), which covers the sacrificial layer SCL, on the color filter layer 220 (operation S232), preparing a temporary material layer PML (see FIG. 38) by curing the target material layer OML (operation S233), and placing a low refractive layer 230 by removing a portion of the temporary material layer PML, which is disposed on the sacrificial layer SCL, together with the sacrificial layer SCL (operation S234).

As illustrated in FIG. 35, in the placing of the sacrificial layer SCL (see FIG. 36) (operation S231), the sacrificial material layer SML may be placed on an entire area of the color filter layer 220.

As illustrated in FIG. 36, in the placing of the sacrificial layer SCL (operation S231), the sacrificial layer SCL may be placed by partially exposing the sacrificial material layer SML through an exposure mask MSK and developing the sacrificial material layer SML.

For example, the exposure mask MSK may include an opening OP which faces at least the display area DA of a second support substrate 210 and transmits light and a blocking portion BK which is a portion other than the opening OP and blocks light.

The opening OP may also face a portion of a non-display area NDA which is adjacent to the display area DA of the second support substrate 210.

Accordingly, the sacrificial layer SCL may be placed in another portion of the non-display area NDA which contacts edges of the second support substrate 210.

As illustrated in FIG. 37, in the placing of the target material layer OML (operation S232), the target material layer OML may be prepared by applying a target material, which covers the sacrificial layer SCL, onto the color filter layer 220.

As illustrated in FIG. 38, in the preparing of the temporary material layer PML (operation S233), the temporary material layer PML may be prepared by performing low-temperature heat treatment HEAT on the target material layer OML (see FIG. 37).

A heat treatment temperature may be a low temperature less than or equal to about 130° C. For example, the heat treatment temperature may be about 110° C.

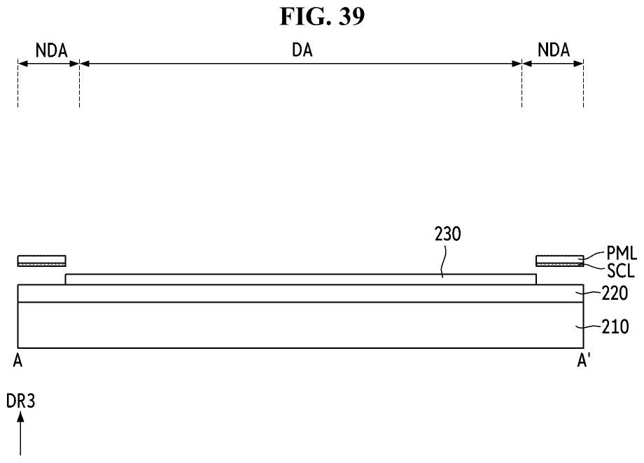

As illustrated in FIG. 39, in the placing of the low refractive layer 230 (operation S234), the low refractive layer 230 may be prepared by separating a portion of the temporary material layer PML which is placed on the sacrificial layer SCL from the color filter layer 220 together with the sacrificial layer SCL by a lift-off method.

According to the embodiment illustrated in FIGS. 34 through 39, in the placing of the low refractive layer 230 (operation S234), the process of partially removing the temporary material layer PML may not be performed by an etching process. Therefore, a defect in which a portion of the color filter layer 220 which is not covered by the low refractive layer 230 is exposed to an etching process and thus damage may be prevented. Moreover, since a portion of the temporary material layer PML which overlaps the sacrificial layer SCL in the third direction DR3 is removed together with the sacrificial layer SCL, a defect in which a portion of the temporary material layer PML partially remains may be prevented.

Since the temporary material layer PML can be placed with a relatively uniform thickness and the sacrificial layer SCL can be placed in a specific shape corresponding to the exposure mask MSK, the low refractive layer 230 may be placed relatively uniformly with a target thickness and a target shape. Therefore, process defects in the placing of the low refractive layer 230 (operation S22) may be further reduced.

Furthermore, according to the embodiment illustrated in FIGS. 34 through 39, in the placing of the low refractive layer 230 (operation S234), a portion of the temporary material layer PML remaining without being peeled off together with the sacrificial layer SCL may be provided as the low refractive layer 230. Accordingly, due to the peeling process, edges of the low refractive layer 230 may have a partially ripped or torn off shape with irregular and fine depressions and elevations.

However, the effects of the disclosure are not restricted to the one set forth herein. The above and other effects of the disclosure will become more apparent to one of daily skill in the art to which the disclosure pertains by referencing the claims.

A display device according to embodiments may include a first substrate and a second substrate facing each other. The second substrate may include a color filter layer on a second support substrate, a low refractive layer disposed on a portion of the color filter layer, and a first capping layer disposed on the color filter layer, including an inorganic insulating material and covering the low refractive layer.

The low refractive layer may include a transparent organic material and hollow silica particles dispersed in the transparent organic material.

Since the first capping layer includes an inorganic insulating material, the low refractive layer may have a refractive index lower than the first capping layer.

As described above, according to embodiments, since the low refractive layer is disposed only on a portion of the color filter layer, upper and side surfaces of the low refractive layer may be completely covered by the inorganic insulating material of the first capping layer.

For example, since the transparent organic material of the low refractive layer is encapsulated by the first capping layer, a penetration path of oxygen or moisture through the low refractive layer may be reduced or delayed.

Therefore, the lifespan and display quality of the display device may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first substrate comprising a first support substrate including emission areas and light emitting elements disposed on the emission areas;
a second substrate facing the first substrate; and
a sealing layer bonding the first substrate and the second substrate together, wherein
the second substrate comprises:
a second support substrate facing the first substrate;
a color filter layer disposed on a surface of the second support substrate;
a low refractive layer disposed on a portion of the color filter layer in the emission areas; and
a first capping layer disposed on the color filter layer, comprising an inorganic insulating material, and covering the low refractive layer, and
the low refractive layer has a refractive index lower than the first capping layer.

2. The display device of claim 1, wherein
the low refractive layer comprises a transparent organic material and hollow silica particles dispersed in the transparent organic material, and
the refractive index of the low refractive layer is in a range of about 1.0 to about 1.5.

3. The display device of claim 1, wherein
each of the first support substrate and the second support substrate comprises a display area in which the emission areas are arranged and a non-display area disposed around the display area,
the display area comprises a non-emission area between the emission areas,
the color filter layer comprises a light blocking portion disposed in the non-emission area and the non-display area and blocking light, and
the low refractive layer is disposed in a portion of the non-display area which is adjacent to the display area and in the display area.

4. The display device of claim 3, wherein
the sealing layer is disposed in the non-display area, and
the low refractive layer is spaced apart from the sealing layer.

5. The display device of claim 3, wherein
the second substrate further comprises a dam portion disposed on the color filter layer in the non-display area and surrounding the display area in a plan view, and
the low refractive layer is disposed in an area surrounded by the dam portion in a plan view.

6. The display device of claim 3, wherein
the emission areas comprise a first emission area emitting light of a first wavelength band, a second emission area emitting light of a second wavelength band lower than the first wavelength band, and a third emission area emitting light of a third wavelength band lower than the second wavelength band,
the color filter layer further comprises a first filter portion disposed in the first emission area and transmitting the light of the first wavelength band, a second filter portion disposed in the second emission area and transmitting the light of the second wavelength band, and a third filter portion disposed in the third emission area and transmitting the light of the third wavelength band, and
the light blocking portion is further disposed in the non-display area on the second support substrate.

7. The display device of claim 6, wherein
the light emitting elements emit light of a fourth wavelength band equal to or lower than the third wavelength band,
the second substrate further comprises a color conversion layer disposed on the first capping layer and a second capping layer disposed on the first capping layer, comprising an inorganic insulating material, and covering the color conversion layer, and
the color conversion layer comprises:
a first color conversion portion disposed in the first emission area and converting the light of the fourth wavelength band into the light of the first wavelength band;
a second color conversion portion disposed in the second emission area and converting the light of the fourth wavelength band into the light of the second wavelength band;
a light transmitting portion disposed in at least a portion of the third emission area and transmitting the light of the fourth wavelength band; and
a partition wall disposed between the first color conversion portion, the second color conversion portion, and the light transmitting portion.

8. The display device of claim 3, wherein
the first substrate comprises:
a circuit layer disposed on the first support substrate and comprising light-emitting pixel drivers electrically connected to the light emitting elements, respectively;
an element layer disposed on the circuit layer and comprising the light emitting elements; and
an enclosing layer covering the element layer,
the element layer further comprises anodes disposed in the emission areas, a pixel defining layer disposed in the non-emission area and covering edges of the anodes, a light emitting layer disposed on the anodes and the pixel defining layer, and a cathode disposed on the light emitting layer, and
each of the light emitting elements has a structure in which the light emitting layer is disposed between an anode and the cathode facing each other.

9. A method of manufacturing a display device, the method comprising:
preparing a first substrate which comprises light emitting elements disposed in emission areas;
preparing a second substrate;
placing a sealing layer on the first substrate or the second substrate; and
bonding the first substrate and the second substrate together using the sealing layer, wherein
the preparing of the second substrate comprises:
placing a color filter layer on a second support substrate;
placing a low refractive layer on a portion of the color filter layer in the emission areas; and
placing a first capping layer which covers the low refractive layer by stacking an inorganic insulating material on the color filter layer, and
in the placing of the low refractive layer, the low refractive layer has a refractive index lower than the first capping layer.

10. The method of claim 9, wherein
each of the first substrate and the second substrate comprises a display area in which the emission areas are arranged and a non-display area disposed around the display area,
the display area comprises a non-emission area between the emission areas,
the color filter layer, in the placing of the color filter layer, comprises a light blocking portion disposed in the non-emission area and the non-display area and blocking light, and
the low refractive layer, in the placing of the low refractive layer, is placed in a portion of the non-display area which is adjacent to the display area and in the display area.

11. The method of claim 10, wherein in the placing of the sealing layer, the sealing layer is placed in the non-display area.

12. The method of claim 10, wherein in the placing of the low refractive layer,
the low refractive layer comprises a transparent organic material and hollow silica particles dispersed in the transparent organic material, and
the refractive index of the low refractive layer is in a range of about 1.0 to about 1.5.

13. The method of claim 12, wherein the placing of the low refractive layer comprises:
placing a target material layer on a portion of the color filter layer by dropping a target material through a nozzle; and
curing the target material layer.

14. The method of claim 13, wherein
the preparing of the second substrate further comprises, before the placing of the low refractive layer, placing a dam portion spaced apart from the display area and surrounding the display area on the color filter layer in the non-display area, and
the placing of the target material layer comprises spreading the target material dropped onto the color filter layer in an area surrounded by the dam portion.

15. The method of claim 12, wherein the placing of the low refractive layer comprises:
placing a target material layer on a portion of the color filter layer by dropping a target material through a nozzle;
preparing a temporary material layer by curing the target material layer on the color filter layer;
placing a mask material layer on the temporary material layer;
preparing an etch mask by removing the mask material layer except for a portion overlapping at least the display area in a plan view; and
partially removing the temporary material layer using the etch mask.

16. The method of claim 12, wherein the placing of the low refractive layer comprises:
placing a sacrificial layer by removing a portion of the sacrificial layer, which overlaps at least the display area in a plan view, on the color filter layer;
placing a target material layer covering the sacrificial layer, on the color filter layer;
preparing a temporary material layer by curing the target material layer; and
removing a portion of the temporary material layer, which is disposed on the sacrificial layer, together with the sacrificial layer.

17. A method of manufacturing a display device, the method comprising:
preparing a first substrate which comprises light emitting elements disposed in emission areas of a display area;
preparing a second substrate;
placing a sealing layer on the first substrate or the second substrate; and
bonding the first substrate and the second substrate together using the sealing layer,
wherein the preparing of the second substrate comprises:
placing a color filter layer on a second support substrate;
placing a sacrificial layer by removing a portion of a sacrificial material layer, which overlaps at least the display area in a plan view, on the color filter layer;
placing a target material layer covering the sacrificial layer on the color filter layer;
preparing a temporary material layer by curing the target material layer; and
placing a low refractive layer in the emission areas on a portion of the color filter layer by removing a portion of the temporary material layer, which is disposed on the sacrificial layer, together with the sacrificial layer.

18. The method of claim 17, wherein
the preparing of the second substrate further comprises placing a first capping layer covering the low refractive layer by stacking an inorganic insulating material on the color filter layer, and
in the placing of the low refractive layer, the low refractive layer has a refractive index lower than the first capping layer,
the low refractive layer comprises a transparent organic material and hollow silica particles dispersed in the transparent organic material, and
the refractive index of the low refractive layer is in a range of about 1.0 to about 1.5.

19. The method of claim 18, wherein
the second support substrate comprises the display area in which the emission areas are arranged and a non-display area disposed around the display area,
the display area comprises a non-emission area between the emission areas,
the color filter layer, in the placing of the color filter layer, comprises a light blocking portion disposed in the non-emission area and the non-display area and blocking light,
the low refractive layer, in the placing of the low refractive layer, is placed in a portion of the non-display area which is adjacent to the display area and in the display area, and
the sealing layer, in the placing of the sealing layer, is placed in the non-display area.

20. An electronic device comprising:
the display device of claim 1; and
a processor that transmits an image data signal to the display device.
